(19) United States
(12) Patent Application Publication
(10) Pub. No.: US 2025/0393431 A1
(43) Pub. Date: Dec. 25, 2025

(54) DISPLAY PANEL

(71) Applicant: HANNSTAR DISPLAY CORPORATION, Taipei City (TW)

(72) Inventors: Jing-Ya Chiu, Tainan City (TW); Qi-En Luo, Chiayi County (TW); Ying-Jung Chen, New Taipei City (TW); Shao-Chien Chang, Taoyuan City (TW); Ling-Chih Kao, New Taipei City (TW); Cheng-Yen Yeh, Taichung City (TW)

(73) Assignee: HANNSTAR DISPLAY CORPORATION, Taipei City (TW)

(21) Appl. No.: 18/970,849

(22) Filed: Dec. 5, 2024

(30) Foreign Application Priority Data
Jun. 20, 2024 (TW) 113122799

(51) Int. Cl. H10K 59/38; H10H 29/85; H10H 29/856; H10K 59/35; H10K 59/80

(52) U.S. Cl. CPC H10K 59/38; H10H 29/8517; H10H 29/856; H10K 59/35; H10K 59/878

(57) ABSTRACT

A display panel including a substrate and a plurality of sub-pixel units is disclosed. The plurality of sub-pixel units are disposed on the substrate, and each of the plurality of sub-pixel units includes a metal reflective layer and a color resist layer. The metal reflective layer has at least one slit. The color resist layer is disposed on the metal reflective layer, and the color resist layer includes a plurality of color resist patterns.

### BACKGROUND OF THE INVENTION

### 1. Field of the Invention

The present invention relates to a display panel, and more particularly to a display panel including a metal reflective layer and a color resist layer.

### 2. Description of the Prior Art

Display panels are used to transmit and display information more conveniently, and have been widely applied in various electronic products, such as notebooks, smart phones, wearable devices, smart watches and display screens for vehicles. A display panel (such as a reflective type display panel or a transflective type display panel) using external light as a light source has the advantage of low energy consumption, which may display images by reflecting the external light. The arrangement of the color resists in the display panel may affect the visual fineness of the image, however, when the product resolution requirement is higher.

### SUMMARY OF THE INVENTION

One of the objectives of the present invention is to provide a display panel, wherein a color resist layer of each sub-pixel unit includes a plurality of color resist patterns, thereby improving the fineness of the image.

In order to achieve the above objectives, the present invention provides a display panel including a substrate and a plurality of sub-pixel units. The plurality of sub-pixel units are disposed on the substrate, and each of the plurality of sub-pixel units includes a metal reflective layer and a color resist layer. The metal reflective layer has at least one slit. The color resist layer is disposed on the metal reflective layer, and the color resist layer includes a plurality of color resist patterns.

According to the display panels of the embodiments of the present invention, a color resist layer of each of the sub-pixel units includes a plurality of color resist patterns, thereby improving the fineness of the image, and the visual effect of the whole display image may be improved. In addition, the metal reflective layer of each of the sub-pixel units has a slit, thereby reducing the light leakage in a dark state.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a partial top-view schematic diagram of a display panel according to a first embodiment of the present invention.

FIG. 2 is a partial cross-sectional schematic diagram of a display panel according to an embodiment of the present invention.

FIG. 3 is a partial top-view schematic diagram of a display panel according to a second embodiment of the present invention.

FIG. 4 is a partial top-view schematic diagram of a display panel according to a third embodiment of the present invention.

FIG. 5 is a partial top-view schematic diagram of a display panel according to a fourth embodiment of the present invention.

FIG. 6 is a partial top-view schematic diagram of a display panel according to a fifth embodiment of the present invention.

FIG. 7 is a partial top-view schematic diagram of a display panel according to a sixth embodiment of the present invention.

### DETAILED DESCRIPTION

For understanding the present invention, the features and desired effects of the present invention are described in detail with reference to the following embodiments, taken in conjunction with the drawings. It should be noted that the drawings are simplified schematic diagrams, so that only the components and their relationships related to the present invention are shown in order to provide a clear description of the basic architecture or implementation of the present invention. It will be understood by one skilled in the art that the practical components and layout may be more detailed. In addition, for the convenience of illustration, the components shown in various drawings of the present invention are not drawn in proportion with respect to their actual number, shape and size in practice, and the detailed proportions thereof may be adjusted according to the design requirements.

In the following description and in the claims, the terms “include”, “comprise” and “have” are used in an open-ended fashion, and thus should be interpreted to mean “include, but not limited to . . . ”. When the terms “include”, “comprise” and/or “have” are used in the description of the present invention, the corresponding features, areas, steps, operations and/or components are not limited to the specific embodiment, and the addition of one or a plurality of the corresponding or other features, areas, steps, operations, components and/or combinations thereof are also included in the scope of the application.

In the present invention, a display panel may be used in a non-self-emissive display device or a self-emissive display device. The display panel may be a reflective type display panel or a transflective type display panel. The reflective type display panel may use an external light as a light source for displaying images. The external light enters the display panel from a side of the display panel facing a user, and the display panel reflects the external light to display a corresponding image, wherein the external light described above may be ambient light (e.g., solar light), but not limited herein. In some embodiments, the display panel may further include a front-light module, and the external light described above may further include the light provided from the front-light module, wherein the front-light module is disposed at the side of the display panel facing the user. The transflective type display panel may further include a backlight module, wherein in addition to using the above external light as a light source for displaying images, the transflective type display panel may further use the light provided from the backlight module as another light source for displaying images, and the backlight module is disposed at a side of the display panel facing away from the user, but this is not limited herein.

It should be noted that the technical features in different embodiments described in the following can be replaced, recombined, or mixed with one another to constitute another embodiment without departing from the spirit of the present invention.

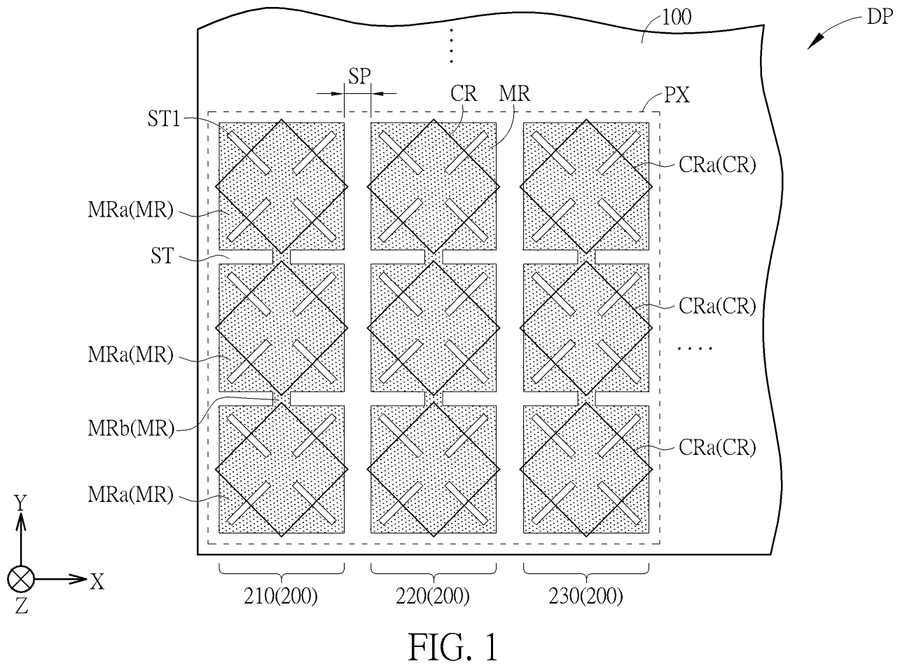

Refer to FIG. 1, which is a partial top-view schematic diagram of a display panel according to a first embodiment of the present invention. As shown in FIG. 1, a display panel DP includes a substrate 100 and a plurality of sub-pixel units 200, and the plurality of sub-pixel units 200 are disposed on the substrate 100. The plurality of sub-pixel units 200 may be disposed in the display region of the display panel DP for displaying images. It should be noted that FIG. 1 only shows the arrangement of a portion of the sub-pixel units 200 on the substrate 100 when the display panel DP is viewed from the top along a direction Z, and more sub-pixel units 200 may be disposed on the substrate 100 in practice, wherein the direction Z may be a top-view direction of the display panel DP and parallel to a normal direction of the upper or lower surface of the substrate 100. In some embodiments, the plurality of sub-pixel units 200 may be arranged side by side in a direction X (which may be referred to as a first direction), but the arrangement of the plurality of sub-pixel units 200 is not limited to the above, and there may be other suitable arrangements or designs according to product requirements. In some embodiments, the plurality of sub-pixel units 200 may be arranged in an array along the direction X and a direction Y (which may be referred to as a second direction), wherein the direction X is different from the direction Y. For example, the direction X may be perpendicular to the direction Y, but not limited herein. The substrate 100 may include a hard substrate or a flexible substrate. The hard substrate includes, for example, glass, ceramics, quartz or sapphire, and the flexible substrate includes, for example, polyimide (PI), polycarbonate (PC), polyethylene terephthalate (PET) or poly(methyl methacrylate) (PMMA), but not limited herein.

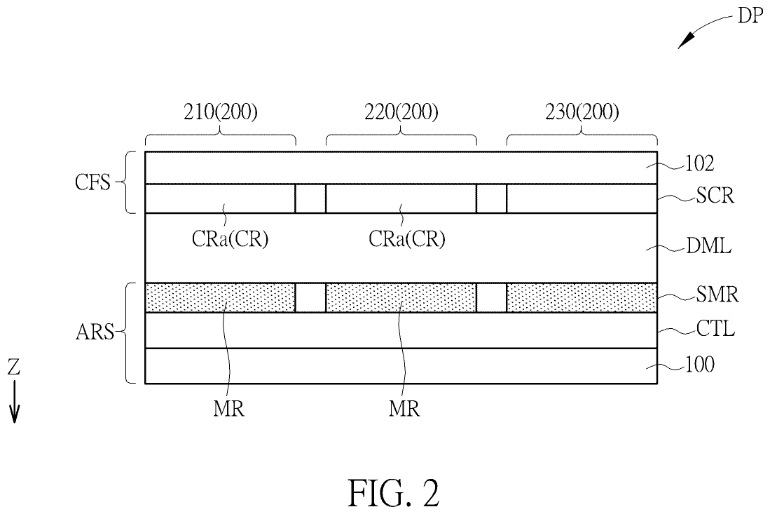

Each of the sub-pixel units 200 includes a metal reflective layer MR and a color resist layer CR, and the color resist layer CR is disposed on the metal reflective layer MR. For example, the display panel DP may include an array substrate and a color filter substrate, which are disposed opposite to each other, the metal reflective layer MR may be disposed at the side of the array substrate, and the color resist layer CR may be disposed at the side of the color filter substrate, but this is not limited herein. In a variant embodiment, the color resist layer CR and the metal reflective layer MR may be disposed at the side of the same substrate, such as both being disposed at the side of the array substrate. In this embodiment, taking the partial cross-sectional view of the display panel DP shown in FIG. 2 as an example, the layer-stacking structure of the display panel DP may be further described in detail, wherein FIG. 2 is a partial cross-sectional schematic diagram of a display panel according to an embodiment of the present invention. According to the embodiment shown in FIG. 2, the display panel DP may include an array substrate ARS and a color filter substrate CFS, which are disposed opposite to each other. The display panel DP may further include a display media layer DML disposed between the array substrate ARS and the color filter substrate CFS, wherein the display media layer DML includes, for example (but not limited to), liquid crystals or light-emitting diodes. The light-emitting diodes may include an organic light-emitting diode (OLED), a mini light-emitting diode (mini LED) or a micro light-emitting diode (micro LED), but not limited herein. The array substrate ARS may include the substrate 100 and a metal reflective structure SMR, and the metal reflective structure SMR is disposed on the substrate 100. The metal reflective layer MR in each sub-pixel unit 200 may be formed of a portion of the metal reflective structure SMR. The array substrate ARS may further include a circuit layer CTL, for example, disposed between the substrate 100 and the metal reflective structure SMR, and the circuit layer CTL may include switching elements, driving elements, wires and/or electrodes for driving the sub-pixel units 200, but not limited herein. In some embodiments, the metal reflective layer MR may also belong to a portion of the circuit layer CTL. The color filter substrate CFS may include another substrate 102 and a color resist structure SCR. The color resist structure SCR may be disposed on the surface of the substrate 102 facing the display media layer DML, i.e., the color resist structure SCR may be disposed on the metal reflective structure SMR and located between the display media layer DML and the substrate 102. The color resist layer CR in each sub-pixel unit 200 may be formed of a portion of the color resist structure SCR. The metal reflective structure SMR may be used to reflect an external light to form a reflected light, and the reflected light may pass through the color resist structure SCR to form a corresponding color light, thereby displaying images. It should be noted that the layer-stacking structure of the display panel DP shown in FIG. 2 is only one of various examples, and the present invention is not limited to the above.

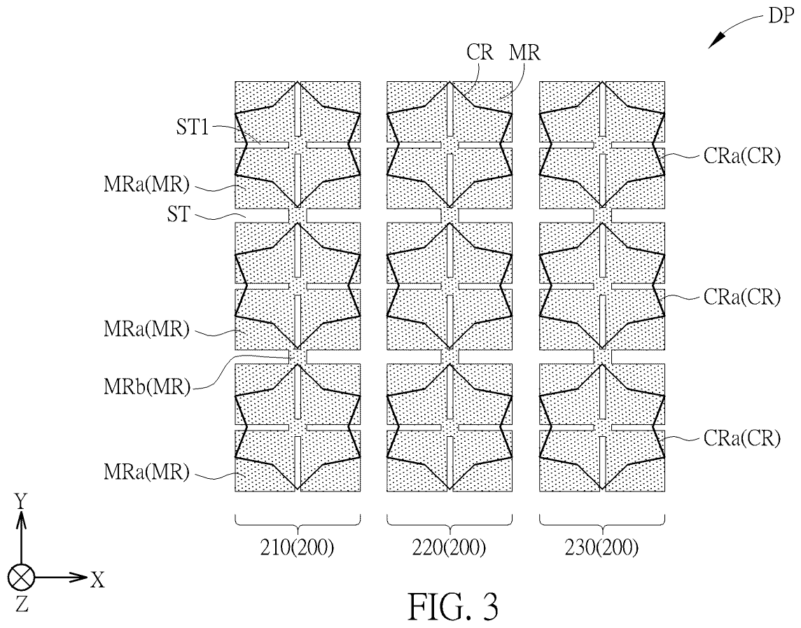

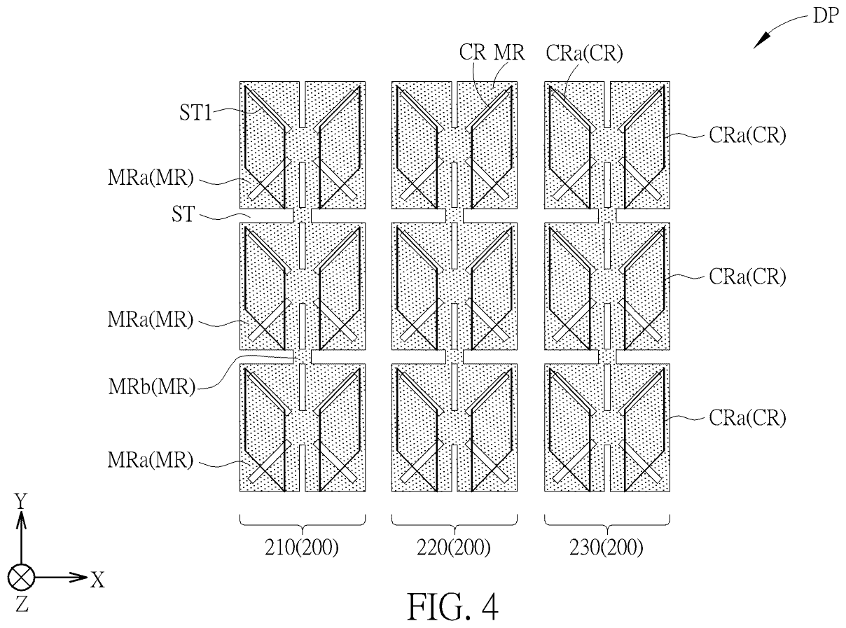

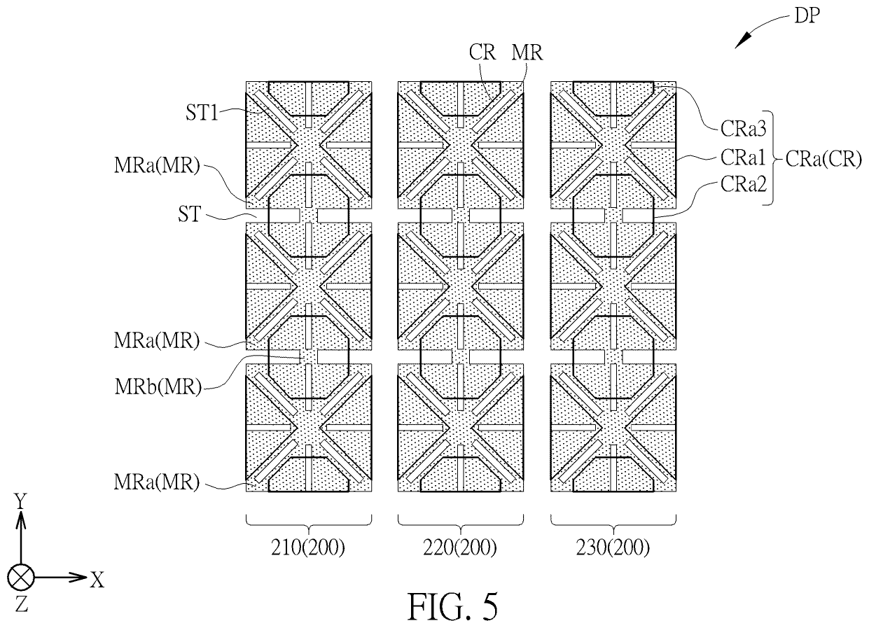

As shown in FIG. 1, the metal reflective layer MR of each of the sub-pixel units 200 has at least one slit ST. Specifically, the metal reflective layer MR of each sub-pixel unit 200 may include a plurality of unit patterns MRa and at least one connection pattern MRb, wherein each connection pattern MRb is connected between two adjacent unit patterns MRa, and the at least one slit ST is located between the two adjacent unit patterns MRa. In some embodiments, the metal reflective layer MR may have a plurality of slits ST, and one slit ST may be respectively formed on both sides of the connection pattern MRb between two adjacent unit patterns MRa, but not limited herein. By forming the slits ST in the metal reflective layer MR of each sub-pixel unit 200, the region where the slit ST is located does not reflect the external light, thereby reducing the light leakage caused by unnecessary reflected light when the display panel DP is in a turned-off state, i.e., the light leakage in a dark state may be reduced, and thus the overall visual effect is improved. In some embodiments, each of the unit patterns MRa may further have a plurality of slits ST1, thereby further reducing the light leakage in the dark state. The plurality of slits ST1 may be arranged in an X shape (as shown in FIG. 1), a cross shape (as shown in FIG. 3), a “*” shape (as shown in FIG. 4), a radial shape (as shown in FIG. 5) or other suitable shapes or distributions. The slits ST and the slits ST1 described above may be formed by, for example (but not limited to), a cutting process. In some embodiments, in the direction X, a space SP may exist between the metal reflective layers MR of two adjacent sub-pixel units 200, i.e., the two adjacent metal reflective layers MR are separated from each other and are not connected with each other, wherein each metal reflective layer MR may be used as an electrode of each sub-pixel unit 200.

In the present invention, the color resist layer CR of each of the sub-pixel units 200 includes a plurality of color resist patterns CRa. Taking the embodiment shown in FIG. 1 as an example, in one sub-pixel unit 200, the metal reflective layer MR may include three unit patterns MRa, the color resist layer CR may include three color resist patterns CRa, and one color resist pattern CRa may correspond to one unit pattern MRa. According to the embodiment shown in FIG. 1, from a top-view of the display panel DP along the direction Z, each of the color resist patterns CRa may be rhombus-shaped, wherein each rhombus-shaped color resist pattern CRa may, for example (but not limited to), have two diagonal lines parallel to the direction X and the direction Y respectively. According to the structure and pattern design of the color resist layer CR, the color resist layer CR of each sub-pixel unit 200 may be divided into multiple color resist patterns CRa of small blocks, and each color resist pattern CRa is polygonal, thereby improving the fineness of the image, as well as the image quality, at different viewing angles. Moreover, the rhombus-shaped color resist patterns CRa may make the optical distribution uniform and reduce the color distortion.

As shown in FIG. 1 and FIG. 2, in some embodiments, the plurality of sub-pixel units 200 may include a first sub-pixel unit 210, a second sub-pixel unit 220 and a third sub-pixel unit 230, which may be arranged side by side in the direction X, wherein the first sub-pixel unit 210 may be a red sub-pixel unit, the second sub-pixel unit 220 may be a green sub-pixel unit, and the third sub-pixel unit 230 may be a blue sub-pixel unit. For example, the color resist layer CR of the first sub-pixel unit 210 may be a red color resist layer, the color resist layer CR of the second sub-pixel unit 220 may be a green color resist layer, and the color resist layer CR of the third sub-pixel unit 230 may be a blue color resist layer, but not limited herein. As shown in FIG. 1, the first sub-pixel unit 210, the second sub-pixel unit 220 and the third sub-pixel unit 230 may form a pixel PX, and the display panel DP may have a plurality of pixels PX arranged in a pixel array along the direction X and the direction Y.

The display panel of the present invention is not limited to the above embodiments. Some embodiments of the display panels of the present invention will be detailed in the following. In order to simplify the illustration, the same elements in the present invention will be labeled with the same symbols. The differences between different embodiments are described in detail below, wherein same features are not described again for the sake of brevity.

Refer to FIG. 3, which is a partial top-view schematic diagram of a display panel according to a second embodiment of the present invention, wherein for the sake of brevity of drawings, only the arrangement of a portion of the sub-pixel units 200 are shown in FIG. 3 and FIG. 4 to FIG. 7, and the substrate 100 (which may be referred to FIG. 1) is omitted. As shown in FIG. 3, from a top-view of the display panel DP along the direction Z, each of the color resist patterns CRa may be star-shaped. For example, the color resist layer CR of each sub-pixel unit 200 may include three star-shaped color resist patterns CRa, wherein each color resist pattern CRa may correspond to one unit pattern MRa. The star-shaped color resist pattern CRa has more sides, which may improve the fineness of the image at different viewing angles and may also improve the resolution and adjust the contrast ratio. In addition, according to the embodiment shown in FIG. 3, each unit pattern MRa may have a plurality of slits ST1, and the plurality of slits ST1 may be arranged in a cross shape to further reduce light leakage in a dark state. One or a plurality of slits ST1 may be adjacent and connected to the outer side of the unit pattern MRa, but this is not limited herein. In a variant embodiment, the slits ST1 may not be connected to the outer side of the unit pattern MRa, as shown in FIG. 1.

Refer to FIG. 4, which is a partial top-view schematic diagram of a display panel according to a third embodiment of the present invention. As shown in FIG. 4, from a top-view of the display panel DP along the direction Z, the plurality of color resist patterns CRa may be arranged in a fishbone pattern along the direction Y. Specifically, the plurality of sub-pixel units 200 may be arranged side by side in the direction X, and the plurality of color resist patterns CRa of each sub-pixel unit 200 are arranged in a fishbone pattern, which may extend along the direction Y, wherein each color resist pattern CRa may be a quadrilateral, such as (but not limited to) a parallelogram. For example, the color resist layer CR of each sub-pixel unit 200 may include six color resist patterns CRa, and the color resist patterns CRa may correspond to one unit pattern MRa in pairs. Two adjacent color resist patterns CRa corresponding to one unit pattern MRa may be arranged symmetrically, and the symmetry axis thereof may be parallel to the direction Y, such that the six color resist patterns CRa are arranged in a fishbone pattern extending along the direction Y. According to the structure and pattern design of the color resist layer CR, the plurality of color resist patterns CRa arranged in the fishbone pattern may improve the fineness of the image at different viewing angles. Furthermore, when the subsequent process is carried out on the color resist layer CR, for example, when rubbing alignment is carried out on an alignment layer (not shown) disposed on the color resist layer CR, since the fishbone pattern arranged by the color resist patterns CRa extends along the direction Y, the probability of encountering obstacles or remaining foreign substances when rubbing alignment is carried out in a direction parallel to the direction Y (e.g., a direction from top to bottom or from bottom to top) is less likely, so that the rubbing mura may be reduced. In addition, according to the embodiment shown in FIG. 4, each unit pattern MRa may have a plurality of slits ST1, and the slits ST1 may be arranged in a “*” shape extending in six different directions, thereby further reducing light leakage in a dark state.

Refer to FIG. 5, which is a partial top-view schematic diagram of a display panel according to a fourth embodiment of the present invention. As shown in FIG. 5, in one sub-pixel unit 200, the plurality of color resist patterns CRa may include triangle shapes and octagon shapes. For example, the color resist layer CR of one sub-pixel unit 200 may include six triangle-shaped color resist patterns CRa1, two octagon-shaped color resist patterns CRa2 and two half-octagon-shaped color resist patterns CRa3 (i.e., the color resist pattern CRa3 shown in FIG. 5 is hexagonal), wherein the color resist pattern CRa3 is half octagonal because only a portion of the sub-pixels 200 are shown in FIG. 5. In practice, when the plurality of sub-pixel units 200 are arranged along the direction Y, two triangle-shaped color resist patterns CRa1 that are symmetrical to each other and one octagon-shaped color resist pattern CRa2 are alternately arranged repeatedly in the top view. According to the structure and pattern design of the color resist layer CR described above, the color resist distribution area may be maximized, so that the aperture ratio of each sub-pixel unit 200 in the display panel DP or the area of the display region of each sub-pixel unit 200 may be improved, thereby further improving the optical visual effect. Moreover, the distribution combination formed by the color resist patterns of two shapes may adjust the contrast ratio in a large area. In addition, according to the embodiment shown in FIG. 5, each unit pattern MRa may have a plurality of slits ST1, and the slits ST1 may be arranged in a radial shape extending in eight different directions, thereby further reducing light leakage in a dark state.

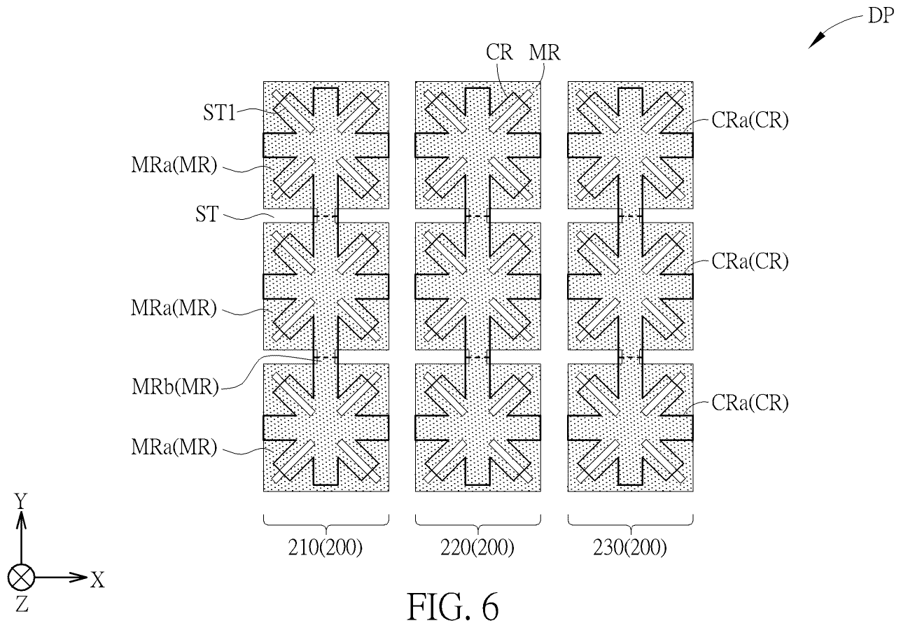

Refer to FIG. 6, which is a partial top-view schematic diagram of a display panel according to a fifth embodiment of the present invention. As shown in FIG. 6, from a top-view of the display panel DP along the direction Z, each of the color resist patterns CRa may be radial-shaped. For example, the color resist layer CR of each sub-pixel unit 200 may include three radial-shaped color resist patterns CRa, wherein each color resist pattern CRa may correspond to one unit pattern MRa. The radial-shaped color resist pattern CRa may extend along eight directions, thereby improving the fineness of the image and the aperture ratio, and wide viewing angle optimization may be achieved.

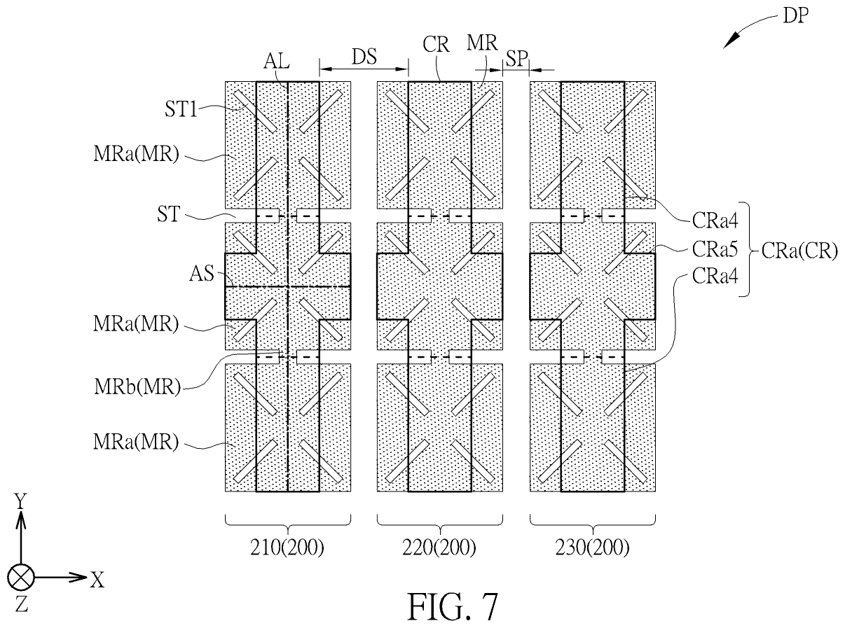

Refer to FIG. 7, which is a partial top-view schematic diagram of a display panel according to a sixth embodiment of the present invention. As shown in FIG. 7, from a top-view of the display panel DP along the direction Z, in one sub-pixel unit 200, the plurality of color resist patterns CRa may together form a cross shape. Specifically, the plurality of sub-pixel units 200 may be arranged side by side in the direction X, the color resist patterns CRa of each sub-pixel unit 200 form a cross shape, and the cross shape has a short axis AS and a long axis AL, wherein the short axis AS may be parallel to the direction X, and the long axis AL may be parallel to the direction Y. For example, the color resist layer CR of each sub-pixel unit 200 may include two quadrilateral color resist patterns CRa4 and one cross-shaped color resist pattern CRa5, and the two color resist patterns CRa4 are respectively located at two sides of the color resist pattern CRa5 in the direction Y, thus forming a cross-shaped pattern with the short axis AS and the long axis AL. According to the structure and pattern design of the color resist layer CR described above, the color resist patterns CRa combined into a cross shape may be in collocation with the rubbing alignment process parallel to the direction X and/or the direction Y, i.e., the probability of encountering obstacles or remaining foreign substances when the rubbing alignment is carried out along the direction X and/or the direction Y on an alignment layer (not shown) disposed on the color resist layer CR is less likely, so that the rubbing mura may be reduced.

According to the embodiment shown in FIG. 7, there is a distance DS in the direction X between the portions of the color resist layers CR of two adjacent sub-pixel units 200 extending in the direction Y, i.e., a distance DS exists between the color resist patterns CRa4 of two adjacent sub-pixel units 200 in the direction X. The distance DS is greater than the space SP between the metal reflective layers MR of two adjacent sub-pixel units 200. Compared with the distance between the color resist layers CR of two adjacent sub-pixel units 200 in other embodiments, the distance DS in this embodiment is larger, i.e., the color resist layers CR of two adjacent sub-pixel units 200 are spaced farther apart, thereby reducing the influence of color mixing of adjacent sub-pixel units 200 on visual effect. In some embodiments, the region where the color resist layer CR is not provided may further be filled with white color resist, so as to improve overall brightness, but this is not limited herein.

From the above description, according to the display panels of the embodiments of the present invention, through the structural design where the color resist layer of each sub-pixel unit includes a plurality of color resist patterns, the fineness of the image and/or the image quality may be improved. In addition, the metal reflective layer of each sub-pixel unit has a slit, thereby reducing the light leakage in a dark state. Furthermore, through the design for the shapes and/or arrangement of the color resist patterns, the visual effect of the whole display image may be improved.

Those skilled in the art will readily observe that numerous modifications and alterations of the device and method may be made while retaining the teachings of the invention. Accordingly, the above disclosure should be construed as limited only by the metes and bounds of the appended claims

What is claimed is:

1. A display panel, comprising:
a substrate; and
a plurality of sub-pixel units disposed on the substrate, wherein each of the sub-pixel units comprises:
a metal reflective layer having at least one slit; and
a color resist layer disposed on the metal reflective layer, wherein the color resist layer comprises a plurality of color resist patterns.

2. The display panel according to claim 1, wherein from a top-view of the display panel, each of the color resist patterns is rhombus-shaped.

3. The display panel according to claim 1, wherein from a top-view of the display panel, each of the color resist patterns is star-shaped or radial-shaped.

4. The display panel according to claim 1, wherein from a top-view of the display panel, the plurality of color resist patterns are arranged in a fishbone pattern.

5. The display panel according to claim 4, wherein the plurality of sub-pixel units are arranged side by side in a first direction, the fishbone pattern extends along a second direction, and the first direction is perpendicular to the second direction.

6. The display panel according to claim 1, wherein from a top-view of the display panel, the plurality of color resist patterns include triangle shapes and octagon shapes.

7. The display panel according to claim 1, wherein from a top-view of the display panel, the plurality of color resist patterns form a cross shape.

8. The display panel according to claim 7, wherein the plurality of sub-pixel units are arranged side by side in a first direction, and the cross shape has a short axis and a long axis, wherein the short axis is parallel to the first direction, the long axis is parallel to a second direction, and the first direction is perpendicular to the second direction.

9. The display panel according to claim 1, wherein the plurality of sub-pixel units comprise a red sub-pixel unit, a green sub-pixel unit and a blue sub-pixel unit.

10. The display panel according to claim 1, wherein each of the metal reflective layers comprises a plurality of unit patterns and at least one connection pattern, the at least one connection pattern is connected between two adjacent unit patterns, and the at least one slit is located between the two adjacent unit patterns.
